(19) United States
(12) Patent Application Publication
(10) Pub. No.: US 2024/0272549 A1
(43) Pub. Date: Aug. 15, 2024

(54) ANTI-WETTING, NON-STICK SURFACES FROM A PHOTOPOLYMER-NANOPARTICLE FORMULATION

(71) Applicant: Ian D. Hosein, Minoa, NY (US)

(72) Inventor: Ian D. Hosein, Minoa, NY (US)

(73) Assignee: Syracuse University, Syracuse, NY (US)

(21) Appl. No.: 18/567,876

(22) PCT Filed: Jun. 7, 2022
(86) PCT No.: PCT/US22/32420

§ 371 Date: Dec. 7, 2023

Related U.S. Application Data
(60) Provisional application No. 63/197,736, filed on Jun. 7, 2021.

(51) Int. Cl. G03F 7/029; C08F 22/10

(52) U.S. Cl. CPC G03F 7/029; C08F 22/1006

(57) ABSTRACT

A polymer film having a non-planar surface defined by a series of surface bumps and a plurality of nanoparticles in the polymer film, wherein the nanoparticles are more concentrated proximately to surface and in the surface bumps to provide anti-wetting and anti-stick properties. The polymer coating is formed by casting a thin layer of a photopolymerizable polymer precursor having a plurality of nanoparticles over a transparent substrate and then irradiating the thin layer from below with a periodic light field so that the photopolymerizable polymer precursor forms a polymer with a non-planar surface and the nanoparticles are concentrated proximately to the non-planar surface as a result of phase separation. The resulting film can be washed with a solvent to remove any uncured polymer and peeled away from the substrate for use as an anti-stick and anti-wetting coating.

### CROSS-REFERENCE TO RELATED APPLICATIONS

The present application claims priority to U.S. Provisional Application No. 63/197,736, filed on Jun. 7, 2021.

### STATEMENT REGARDING FEDERALLY SPONSORED RESEARCH AND DEVELOPMENT

This invention was made with government support under Grant No. 1751621 awarded by the National Science Foundation. The government has certain rights in the invention.

### BACKGROUND OF THE INVENTION

### 1. Field of the Invention

The present invention relates to polymer surfaces and, more specifically, to a photopolymerized polymer and nanoparticles disbursed in the polymer.

### 2. Description of the Related Art

Polymer coatings are typically applied as a thin film to surfaces to confer certain benefits, such as anti-stick and anti-wetting properties, to the surface. For example, surfaces of residential homes and commercial buildings, pneumatic and hydraulic piping systems, as well as automobiles and other transportation systems often benefit from protective coatings and surfaces. Conventional coatings can require, however, multiple steps to prepare and apply, thereby making use of the coatings complicated and expensive to implement. Accordingly, there is a need in the art for a coating that is simple to prepare and apply while still providing the desired properties.

### BRIEF SUMMARY OF THE INVENTION

The present invention comprises a polymer film having a non-planar surface defined by a series of surface bumps and a plurality of nanoparticles in the polymer film, wherein the nanoparticles are more concentrated proximately to surface and in the surface bumps. The non-planar surface and distribution of nanoparticles in the surface features provides anti-wetting and anti-stick properties to the film. More specifically, the present invention provides a film formed from a polymer and having non-planar surface defined by a series of periodically spaced peaks and a series of periodically troughs and a plurality of nanoparticles in the polymer of the film, wherein the nanoparticles are present in a higher concentration proximately to the non-planar surface and in the series of periodically spaced peaks. The plurality of nanoparticles are present in the polymer film in an amount between one and sixteen percent of the polymer by weight. The polymer film may be less than 100 nanometers in thickness. The series of periodically spaced peaks and the series of periodically troughs provide a micrometer to sub-millimeter variation to the non-planar surface. The nanoparticles may be titania or silicon dioxide. The nanoparticles may also be surface functionalized with such organized molecules as (3-aminopropyl) trimethoxysilane. The polymer may be selected from the group consisting of acrylates, methacrylates, vinyls, and thiol-lenes. The polymer may be trimethylolpropane triacrylate.

The present invention also includes a method of forming a film comprising the steps of casting a layer of a polymer precursor having a plurality of nanoparticles over a transparent substrate and then irradiating the layer of the polymer precursor through the transparent substrate with a periodic light field such that the polymer precursor polymerizes to form a film having a non-planar surface defined by a series of periodically spaced peaks and a series of periodically troughs and a higher concentration of the plurality of nanoparticles positioned proximately to the non-planar surface in the series of periodically spaced peaks. Irradiation is continued until all of the photopolymerizable polymer precursor has cured. The resulting film can be washed with a solvent to remove any uncured polymer and peeled away from the substrate for use as an anti-stick and anti-wetting coating.

### BRIEF DESCRIPTION OF THE SEVERAL VIEWS OF THE DRAWING(S)

The present invention will be more fully understood and appreciated by reading the following Detailed Description in conjunction with the accompanying drawings, in which:

FIG. 1 is a schematic showing polymer coatings according to the present invention being formed via a photopolymerization process that results in micropatterned surfaces, with panel a) showing an initially homogenous monomer-nanoparticle, which upon photopolymerization through a photomask leads to a patterned surface with micrometer sized bumps, as shown in panel b), with the magnified inset showing phase-separated nanoparticles collecting toward the surface of the bump-like structures.

FIG. 2 is a series of cross-sectional scanning electron microscope images and energy dispersive spectroscopy maps shown for samples containing, in panels a-b) 5% nanoparticles, panels c-d) 8% nanoparticles, and panels e-f) 16% nanoparticles, all obtained with an exposure time of 24 hours.

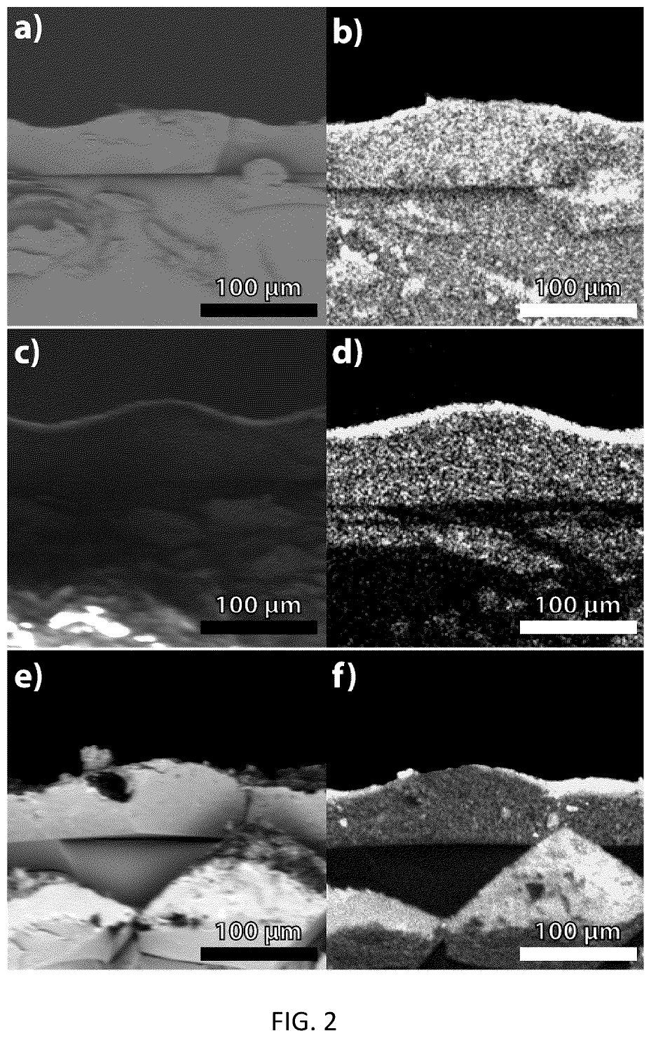

FIG. 3 is a series of top-down SEM images for photopolymerized samples containing panels a) 5% nanoparticles, panels b) 8% nanoparticles, and panels c) 16% nanoparticles, all obtained after exposure for 24 hours. Insets represent the top surface of a single bump.

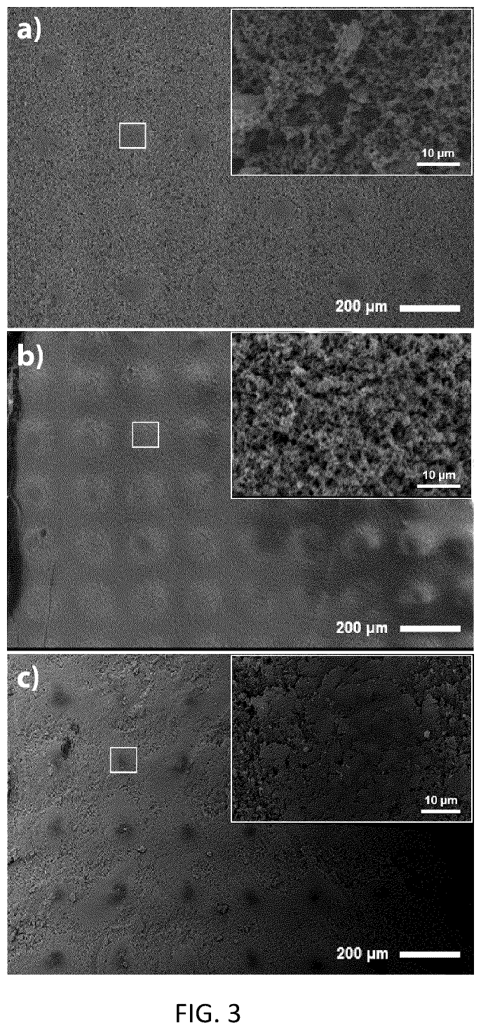

FIG. 4A is a series of goniometer images taken during advancing and receding measurements for samples containing panels a-b) 5% nanoparticles, panels d-e) 8% nanoparticles, and panels g-h) 16% nanoparticles, all obtained after an exposure time of 24 hours.

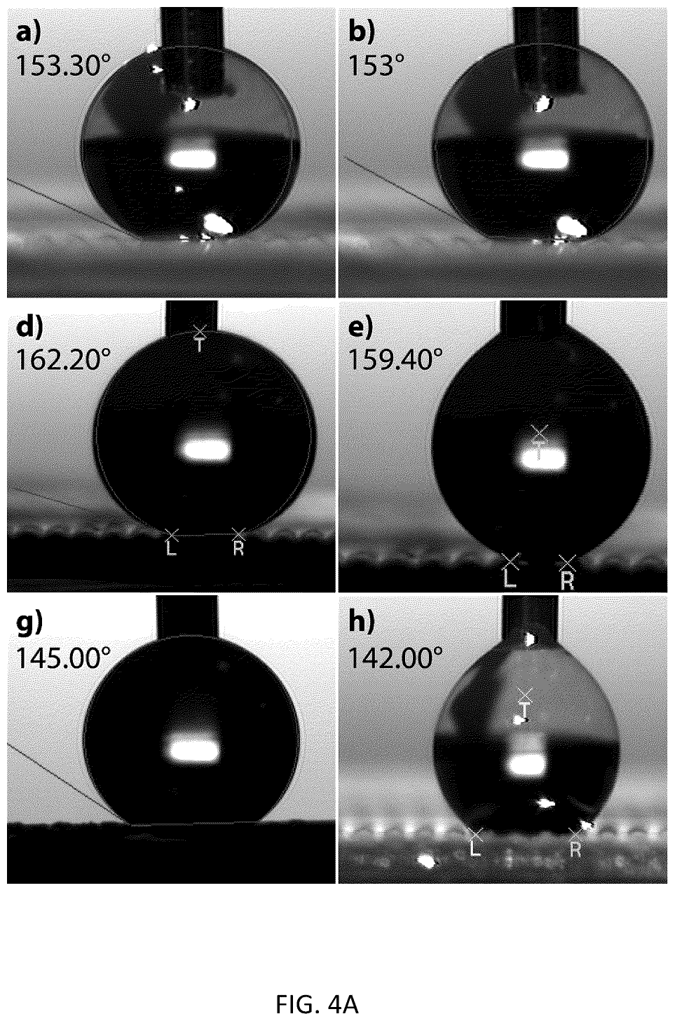

FIG. 4B is a series of bar plots summarizing advancing and receding contact angle values as well as contact angle hysteresis values for samples obtained at different exposure times containing panel c) 5% nanoparticles, panel f) 8% nanoparticles, and panel i) 16% nanoparticles.

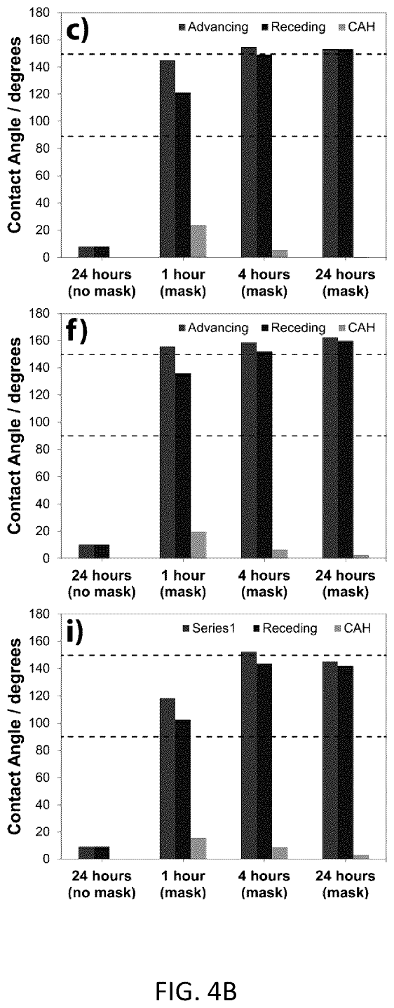

FIG. 5 is a series of digital photographs showing exemplary post-processability of an 8%, 4 hours sample obtained by photopolymerization over a 20 cm² area shown in panel a). The same sample peeled-off and bent to demonstrate flexibility, shown in panel b), free-standing ability and retention of superhydrophobicity shown using a sessile water droplet in panel c), and lastly, section of the same sample peeled-off and attached to different substrates as shown in panel d).

FIG. 6 is a panel of digital photographs a-e) showing the non-stick nature of an 8%, 24 hours sample by placing and removing a sessile water droplet on the surface of the sample. Yellow boxes in panels d) and e) indicate the region of contact between the droplet and the surface of the sample where no residue of water is found after droplet removal. Similarly, panels f-i) show a curved 8%, 24 hours sample with a water droplet bouncing off the surface of the sample and sticking to a rubber glove as shown in panel i), indicating exemplary non-wetting characteristics of the sample.

FIG. 7 is a series of digital photographs showing the self-cleaning ability of an 8%, 24 hours sample. Panel a) shows a dust-covered surface just prior to being cleaned by suspending a water droplet on to it. Panels b-d) indicate the water droplet bouncing onto and away from the surface of the sample and towards the less hydrophobic plastic substrate after collecting dust from the surface. Panel e) shows a sessile water droplet placed on the same surface, whereas panels f-h) show the sample being tilted to roll the droplet, which also leads to a clean surface.

### DETAILED DESCRIPTION OF THE INVENTION

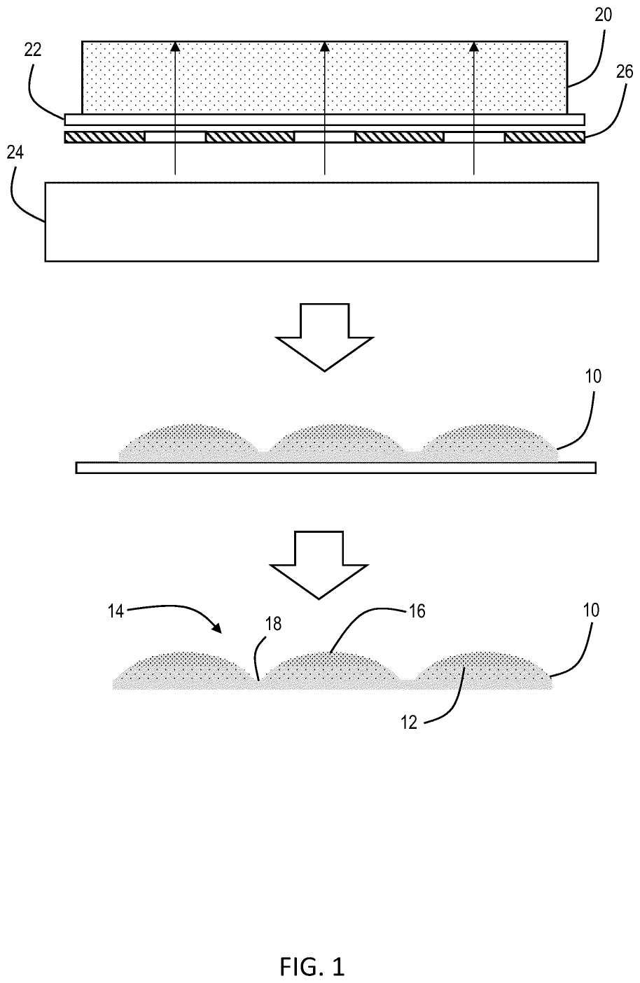

Referring to the figures, wherein like numerals refer to like parts throughout, there is seen in FIG. 1 a photo-polymerized polymer film 10 including a plurality of nanoparticles 12. Film 10 has a non-planar upper surface 14 defined by a series of periodically spaced peaks 16 and a series of periodically spaced troughs 18. Nanoparticles 12 are concentrated in the upper regions of film 10 and more specifically, in the upper regions of peaks 16. The structure of film 10 is formed using a photo-reactive formulation of a polymer precursor 20 (e.g., a monomer) having nanoparticles 12 dispersed therein. Film 10 is formed via photopolymerization using a transparent substrate 22 on which precursor 20 is positioned, then then using an illumination source 24 positioned below substrate 22 that can direct irradiation upwardly. A photomask 26 having a series of apertures defining the locations of the series of periodically spaced peaks 16 is positioned between illumination source 24 and substrate 22 to direct the illumination only into the locations where peaks 16 are to be formed. The act of photopolymerization induces the formation of peaks 16 and troughs 18 as precursor 20 polymerizes and, as a result of phase separation, causes nanoparticles 12 to be concentrated toward the upper surface of peaks 16 so that nanoparticles 12 are present in a higher concentration proximately to non-planar surface 14 of film 10 and in the series of periodically spaced peaks 16.

In a first embodiment, a thin formulation (<100 μm) is cast over a transparent substrate. A periodic light field irradiates the formulation from below. The polymer cures a structure consisting of peaks and troughs corresponding to the irradiated and non-irradiated regions, respectively. Concurrently, the nanoparticles phase-separate from the formulation, producing a uniform coating of nanoparticles on the surface of the polymer. This process creates non-planar surfaces consisting of periodically space peaks and troughs in the polymer substrate, combined with a thin nanoparticle coating that is phase separated upward onto the surface of the polymer structure. The nanoparticle coating is highly porous at the nanoscale. During the irradiation with UV (365 nm) light, all polymer is completely reacted, leaving the final material. Remnant, unreactive photopolymer may be removed through washing in solvent. The final thin film comprising the structure may be peeled off the transparent substrate for use.

The difference between the height of the peaks and the depths of the troughs in the polymer layer can be varied using curing time (1-24 hours), as well as the content of the photoinitiator (0.5-3%). The combination of the sub-millimeter to micrometer scale texture of the polymer and the nanoscale roughness of the nanoparticle layer enables the surface to perform as a robust non-wetting and non-stick surface. Nanoparticle concentrations can be from 1% up to 16% by weight. The extent of the surface coverage of the nanoparticles as well as the nanoparticle coating thickness is varied by varying the weight fraction of the nanoparticles in the formulation.

The pattern of the light may be controlled using a photomask, such as an array of circular holes in a periodic arrangement. The irradiating light source is passed first through this mask to generate a multitude of uniformly sized optical beams which are then passed through the transparent substrate upward into the photoreactive formulation. The polymer structure can be tuned by changing the optical pattern via the photomask design. In the present embodiment, the aperture size can range from 1 to 50 microns and the spacing can range from, in terms of spacing to diameter ratios, of 2 to 10.

The present invention may include any polymer that can undergo free-radical polymerization, including acrylates, methacrylates, vinyls, thiol-lenes. These polymers may comprise higher functionality, as well as formulations and their blends. Blends of free-radical polymers with other non-reactive polymers are also possible. In an example of the present invention, trimethylolpropane triacrylate (TMPTA) was used as the photo-reactive polymer.

Nanoparticles useful for the present invention may be used have sizes up to 500 nm. The composition of the nanoparticle can be all forms of inorganic materials, including ceramics, metals, semiconductors. Specific nanoparticles that can confer anti-wetting and non-stick properties include titania (TiO₂) and silicon dioxide (SiO₂). Other metal oxides and ceramics may also be used including iron oxides. Dense, crosslinked polymer nanoparticles may also be used. The nanoparticles may also be surface functionalized with organic molecules to enhance the anti-wetting properties. Additionally, surface functionalization of the nanoparticles may be employed, such as with (3-aminopropyl) trimethoxysilane. For anti-wetting coatings, titania and silica nanoparticles with weight fractions above 5% but below 16% provide anti-wetting water contact angles greater than 150 degrees, rendering the surface superhydrophobic. Titania and silica nanoparticles with weight fractions above 5% but below 16% can also be used to provide superoleophobic surfaces. By tuning the nanoparticle composition, the surface can be made to resist wetting from a range of polymer to nonpolar solvents. Solvents include water, alcohols, alkanes, a range of fossil fuel based oils as well as organic (vegetable oils).

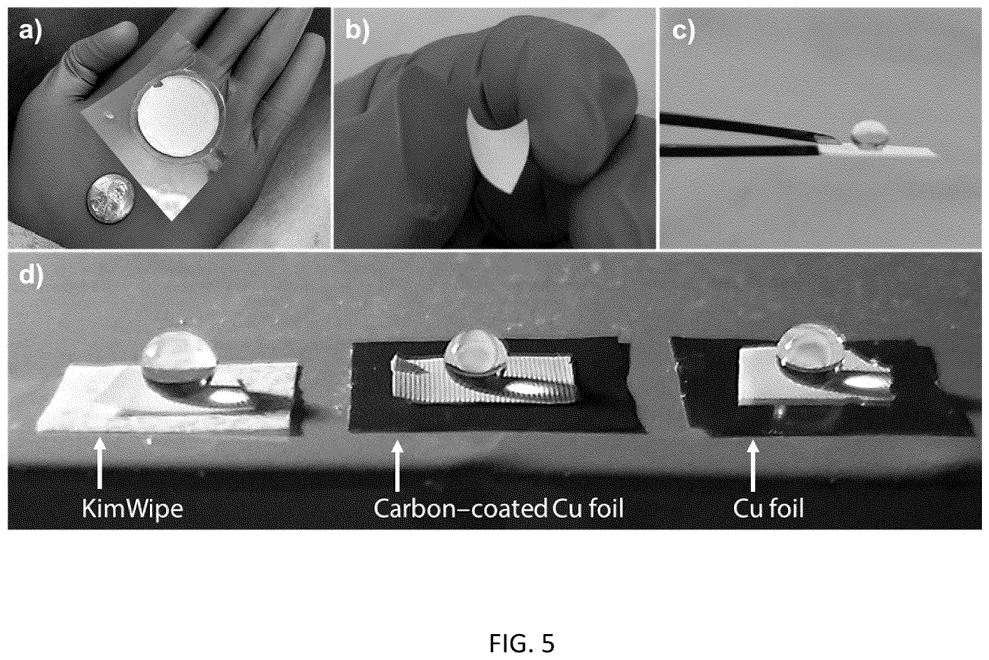

Anti-wetting films according to the present invention can be peeled of the transparent substrate and adhered to any planar surface. In most embodiment, the formulation result in a coating that is flexible, seen in FIG. 5. More flexibility can be achieved by formulating with or using elastomeric polymers. Alternatively, more rigid materials may be formed by formulating with or using more rigid polymers.

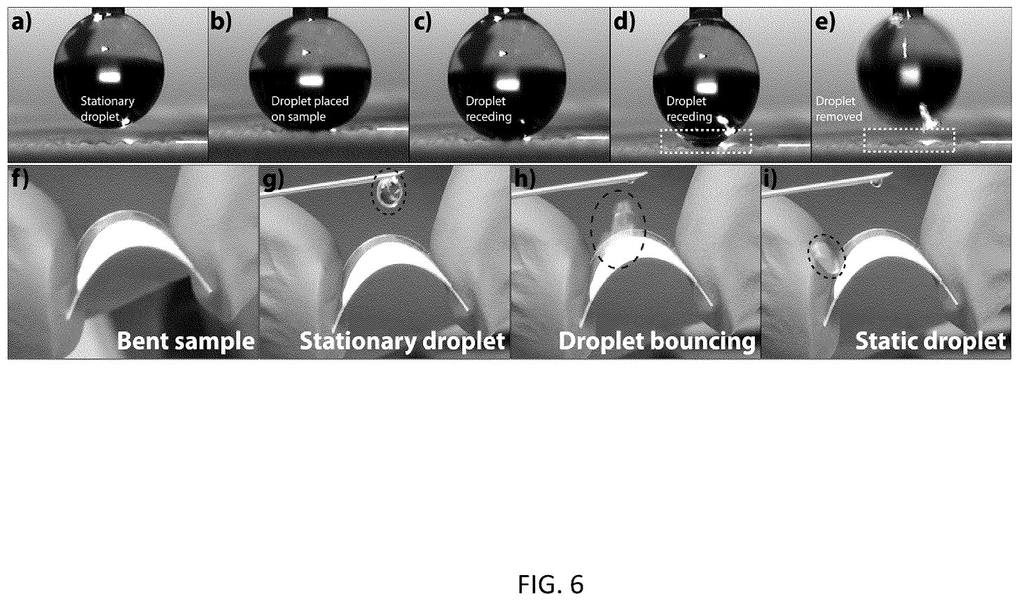

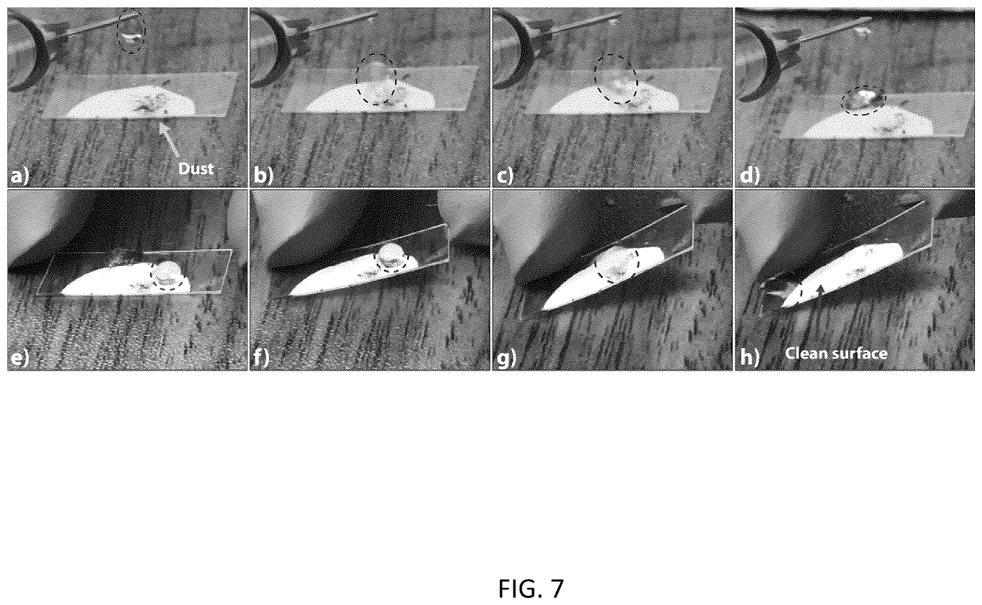

Exemplary coatings display strong water repellency, see FIG. 5 bottom row, and nonstick properties, see FIG. 6, top row. Coatings according to the present invention also provide self-cleaning properties, with dust and debris being easily removed via washing with water, as seen FIG. 7.

What is claimed is:

1. A polymer film, comprising:
a layer formed from a polymer and having non-planar surface defined by a series of periodically spaced peaks and a series of periodically troughs; and
a plurality of nanoparticles in the polymer of the film, wherein the nanoparticles are present in a higher concentration proximately to the non-planar surface and in the series of periodically spaced peaks.

2. The polymer coating of claim 1, wherein the plurality of nanoparticles are present in the polymer film in an amount between one and sixteen percent of the polymer by weight.

3. The polymer coating of claim 2, wherein the polymer film is less than 100 nanometers in thickness.

4. The polymer coating of claim 3, wherein the series of periodically spaced peaks and the series of periodically troughs provide a micrometer to sub-millimeter variation to the non-planar surface.

5. The polymer coating of claim 4, wherein the nanoparticles are formed from a material selected from the group consisting of titania and silicon dioxide.

6. The polymer coating of claim 5, wherein the nanoparticles further include a material selected from the group consisting of metal oxides and ceramics.

7. The polymer coating of claim 6, wherein the polymer is selected from the group consisting of acrylates, methacrylates, vinyls, and thiol-lenes.

8. The polymer coating of claim 7, wherein the polymer is trimethylolpropane triacrylate.

9. A method of forming a polymer coating, comprising the steps of:
casting a layer of a polymer precursor having a plurality of nanoparticles over a transparent substrate;
irradiating the layer of the polymer precursor through the transparent substrate with a periodic light field such that the polymer precursor polymerizes to form a film having a non-planar surface defined by a series of periodically spaced peaks and a series of periodically troughs and a higher concentration of the plurality of nanoparticles positioned proximately to the non-planar surface in the series of periodically spaced peaks.

10. The method of claim 9, wherein the step of irradiating the layer of the polymer precursor through the transparent substrate with the periodic light field comprises irradiating the layer of the polymer precursor through a photomask having a plurality of apertures arranged to allow illumination to pass through and form the series of periodically spaced peaks in the film.

11. The method of claim 10, wherein each of the plurality of apertures comprises a circular hole having a diameter of between one and fifty micrometers.

12. The method of claim 11, wherein each of the plurality of apertures are spaced apart from any adjacent of the plurality of apertures by between two and ten micrometers.

13. The method of claim 12, wherein the step of irradiating the layer of the polymer precursor through the transparent substrate causes the plurality of nanoparticles to phase separate from polymer precursor while the polymer precursor polymerizes such that the nanoparticles become more concentrated where the series of periodically spaced peaks are formed.

14. The method of claim 13, wherein the polymer precursor includes between 0.5 and three percent of a photoinitiator.
